(19) United States
(12) Patent Application Publication
(10) Pub. No.: US 2018/0084648 A1
(43) Pub. Date: Mar. 22, 2018

(54) THREE-DIMENSIONAL WIRING BOARD AND METHOD FOR MANUFACTURING THREE-DIMENSIONAL WIRING BOARD

(71) Applicant: OLYMPUS CORPORATION, TOKYO (JP)

(72) Inventor: Takahide MIYAWAKI, Kamiina-gun (JP)

(73) Assignee: OLYMPUS CORPORATION, TOKYO (JP)

(21) Appl. No.: 15/811,901

(22) Filed: Nov. 14, 2017

Related U.S. Application Data
(63) Continuation of application No. PCT/JP2015/064854, filed on May 25, 2015.

(51) Int. Cl. H05K 1/18; H05K 3/30; H05K 3/34; H05K 1/14; H05K 3/36

(52) U.S. Cl. CPC H05K 1/186; H05K 3/301; H05K 3/3494; H05K 1/145; H05K 2201/042; H05K 2201/10015; H05K 2201/10022; H05K 2201/09854; H05K 2201/10636; H05K 3/368

(57) ABSTRACT

A three-dimensional wiring board includes a chip component including a first end electrode and a second end electrode, a first wiring board with a recessed portion including a first junction electrode on a bottom surface, and a second wiring board, disposed on the first wiring board, including a second junction electrode, where the chip component is vertically housed in the recessed portion, the first end electrode is joined to the first junction electrode, and the second end electrode is joined to the second junction electrode.

### CROSS REFERENCE TO RELATED APPLICATION

This application is a continuation application of PCT/JP2015/064854 filed on May 25, 2015, the entire contents of which are incorporated herein by this reference.

### BACKGROUND OF INVENTION

### 1. Field of the Invention

The present invention relates to a three-dimensional wiring board on which a chip electronic component is mounted, and a method for manufacturing the three-dimensional wiring board.

### 2. Description of the Related Art

Japanese Patent Application Laid-Open Publication No. 64-24493 discloses a method for mounting chip electronic components (hereinafter referred to as “chip component(s)”) on a wiring board at a high density, according to which holes or grooves are formed in a wiring board and chip components are mounted by being vertically placed inside the holes or the grooves.

Here, to efficiently mount chip components on the wiring board, an automatic mounting machine (mounter) is used. For example, a chip component fixed to a carrier tape is temporarily fixed after being placed at a predetermined position of the wiring board by the mounter.

### SUMMARY OF THE INVENTION

A three-dimensional wiring board according to an aspect of the present invention is a three-dimensional wiring board including a chip electronic component including a first end electrode on a first end surface and a second end electrode on a second end surface opposite the first end surface, and a first wiring board with a recessed portion including a first junction electrode on a bottom surface, where the three-dimensional wiring board further includes a second wiring board, disposed on the first wiring board, including a second junction electrode, and the chip electronic component is vertically housed in the recessed portion, the first end electrode is joined to the first junction electrode, and the second end electrode is joined to the second junction electrode.

A method, according to another aspect of the present invention, for manufacturing a three-dimensional wiring board is a method for manufacturing a three-dimensional wiring board including a chip electronic component including a first end electrode on a first end surface and a second end electrode on a second end surface opposite the first end surface, and a first wiring board with a recessed portion including a first junction electrode on a bottom surface, the method including horizontally placing the chip electronic component on the first wiring board with a center of gravity positioned at an opening of the recessed portion, causing the chip electronic component to be vertically housed in the recessed portion by gravity, placing a second wiring board including a second junction electrode on an upper surface of the first wiring board, and solder-joining, by reflow processing, the first end electrode and the first junction electrode, and the second end electrode and the second junction electrode.

### BRIEF DESCRIPTION OF THE DRAWINGS

FIG. 1 is an exposed view of a three-dimensional wiring board according to a first embodiment;

FIG. 2 is a cross-sectional view of the three-dimensional wiring board according to the first embodiment;

FIG. 3 is a cross-sectional view for describing a method for manufacturing the three-dimensional wiring board according to the first embodiment;

FIG. 4 is a cross-sectional view for describing the method for manufacturing the three-dimensional wiring board according to the first embodiment;

FIG. 5 is a cross-sectional view for describing the method for manufacturing the three-dimensional wiring board according to the first embodiment;

FIG. 6 is a cross-sectional view for describing the method for manufacturing the three-dimensional wiring board according to the first embodiment;

FIG. 7 is a cross-sectional view for describing the method for manufacturing the three-dimensional wiring board according to the first embodiment;

FIG. 8 is a cross-sectional view of a three-dimensional wiring board according to a second embodiment;

FIG. 9 is a cross-sectional view of a three-dimensional wiring board according to a third embodiment;

FIG. 10 is a cross-sectional view of a three-dimensional wiring board according to a fourth embodiment;

FIG. 11 is a partial perspective view of a three-dimensional wiring board according to a fifth embodiment; and

FIG. 12 is a cross-sectional view of an image pickup apparatus including the three-dimensional wiring board according to the fifth embodiment.

### DETAILED DESCRIPTION OF THE PREFERRED EMBODIMENTS

### First Embodiment

Hereinafter, a three-dimensional wiring board 1 according to a first embodiment of the present invention will be described with reference to the drawings. Note that the drawings are schematic, and the relationship between a thickness and a width of each member, the ratio of thicknesses of members and the like are not actual. Moreover, the relationship between dimensions and the ratios may be different between the drawings. Moreover, some components, such as solder and wires, may be omitted from the drawings.

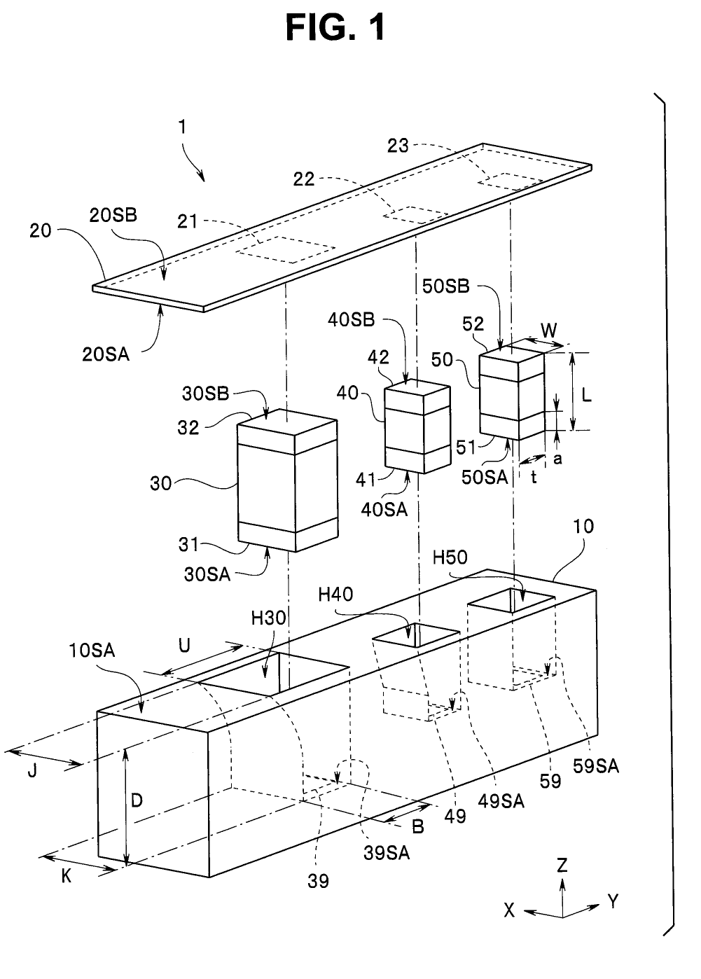

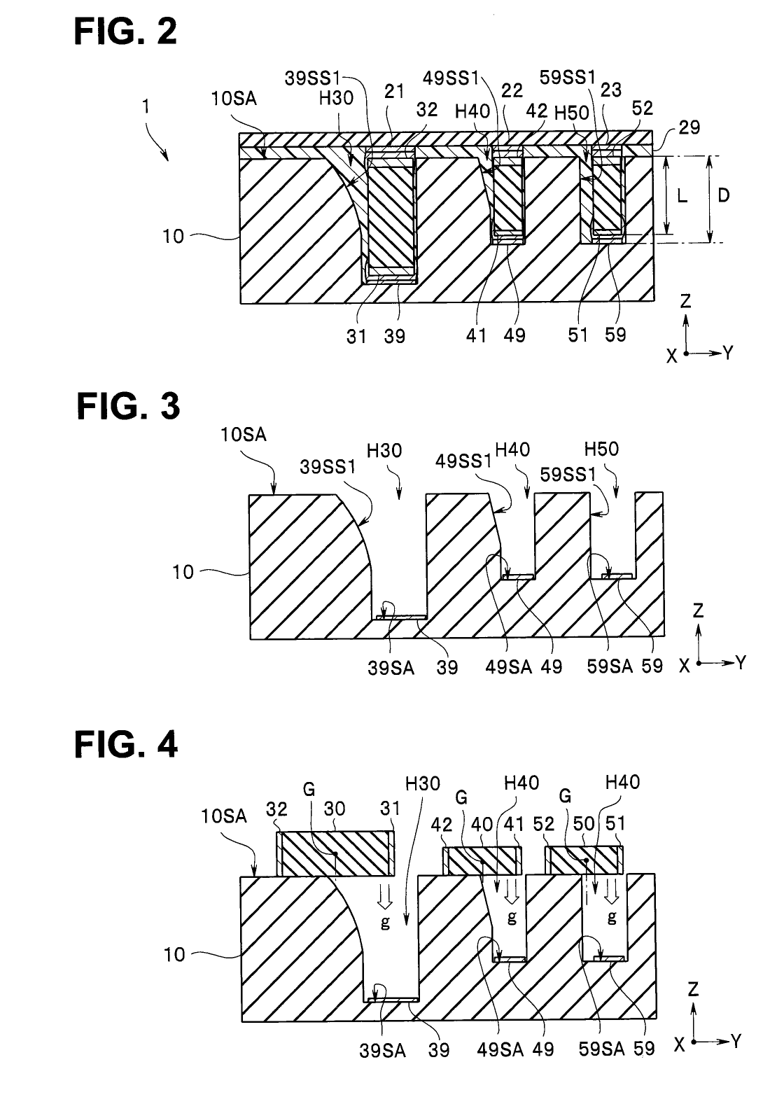

As shown in FIGS. 1 and 2, the three-dimensional wiring board 1 includes a first wiring board 10, a second wiring board 20, and three square chip components 30, 40, 50. Note that FIG. 1 does not show a sealing resin 29 sealing between the first wiring board 10 and the second wiring board 20.

The chip component 30 includes a first end electrode 31 on a first end surface 30SA, and a second end electrode 32 on a second end surface 30SB opposite the first end surface 30SA. The chip components 40, 50 respectively include first end electrodes 41, 51 on first end surfaces 40SA, 50SA, and second end electrodes 42, 52 on second end surfaces 40SB, 50SB. Note that the chip components 30 and the like are for surface mounting, and thus, the end electrodes 31 and the like are extended to side surfaces. The first end electrodes 41 and the like are formed of an Ni/Sn film, for example.

Note that the chip components 30 and the like are left-right symmetric, and thus, for example, the first end electrode 31 and the second end electrode 32 have the same structure, and the two cannot be distinguished from each other until they are disposed on a wiring board.

The first wiring board 10 has three recessed portions H30, H40, H50, each with an opening on a first main surface 10SA. First junction electrodes 39, 49, 59 are disposed respectively, on bottom surfaces 39SA, 49SA, 59SA of the recessed portions H30, H40, H50. The first junction electrodes 39 and the like are formed of a Cu/Ni/Au film, for example.

Note that, in the following, a depth of the recessed portion will be indicated by D, a length of the opening by U, a width of the opening by J, a length of the bottom surface by B, and a width of the bottom surface by K, as shown in FIG. 1. Note that the width J of the opening and the width K of the bottom surface are the same. With respect to the chip component, a length is indicated by L, a width by W, a thickness by t, and an extension length of the end electrode to the side surface by a. Note that the length U of the opening of the recessed portion is the length of a longest side.

One wall surface 39SS1 of the recessed portion H30 is chamfered into a curved surface, and one wall surface 49SS1 of the recessed portion H40 is chamfered into a flat surface. Note that the chamfered wall surfaces 39SS1, 49SS1 are surfaces facing main surfaces of the chip components 30, 40, and are surfaces below the chip components 30, 40 when the chip components 30, 40 are horizontally placed.

On the other hand, a wall surface 59SS1 of the recessed portion H50 is not chamfered, and four wall surfaces are all perpendicular to the first main surface 10SA. Accordingly, lengths U30, U40 of the openings of the recessed portions H30, H40 are longer than lengths B30, B40 of the bottom surfaces, but a length U50 of the opening of the recessed portion H50 is the same as a length B50 of the bottom surface.

Moreover, three second junction electrodes 21, 22, 23 are provided on a first main surface 20SA of the second wiring board 20 including the first main surface 20SA and a second main surface 20SB. The second wiring board 20 is disposed on the first wiring board 10.

The first junction electrodes 39, 49, 59 are disposed on the bottom surfaces 39SA, 49SA, 59SA of the recessed portions H30, H40, H50. Sizes of the first junction electrodes 39, 49, 59 are substantially the same as sizes of the end surfaces 30SA, 40SA, 50SA of the chip components 30, 40, 50. The first junction electrodes 39 and the like are connected to wires not shown.

The chip component 30 is vertically housed in the recessed portion H30, and the first end electrode 31 is solder-joined to the first junction electrode 39. The second end electrode 32 is solder-joined to the second junction electrode 21. The chip components 40, 50 are vertically housed in the recessed portions H40, H50 respectively, and the first end electrodes 41, 51 are solder-joined to the first junction electrodes 49, 59 respectively. The second junction electrodes 21, 22, 23 of the second wiring board 20 are disposed at positions that face the first junction electrodes 39, 49, 59 when the second junction electrodes 21, 22, 23 are disposed on the first wiring board 10. Accordingly, the second end electrodes 42, 52 are solder-joined to the second junction electrodes 22, 23.

The first wiring board 10 is formed of a molded interconnect device (MID) on which a conductive pattern is formed. A base material of the first wiring board 10 is a non-conductive resin, or more particularly, an engineering plastic that can be molded. For example, the base material is of polyamide (PA), polycarbonate (PC), liquid crystal polymer (LCP), polyether ether ketone (PEEK), nylon, polyphthalamide (PPA), acrylonitrile-butadiene-styrene resin (ABS) or the like mixed with an inorganic filler. Note that the base material of the first wiring board 10 may be a ceramic such as alumina, as long as the material is an insulating material.

The first junction electrodes 39 and the like of the first wiring board 10 are made by a laser removal method or a pattern plating method, for example. According to the laser removal method, a conductive film is formed of a plating method or the like on the entire surface of a molded body, and then, unnecessary parts are removed by laser irradiation. According to the pattern plating method, a mask pattern is disposed on the surface of a molded body, and a plating film is formed on a region not covered by the mask. Furthermore, a plating film may be formed at only a region with a catalyst layer, by patterning a catalyst layer of an electroless plating. Note that, although not shown, a plurality of conductive wires, a plurality of electrode pads and the like are also disposed on the first wiring board 10, in addition to the first junction electrodes 39, 49, 59.

The second wiring board 20 is a flexible wiring board using polyimide for a substrate, for example. However, as described later, the second end surfaces 30SB, 40SB, 50SB of the chip components 30, 40, 50 are on the same plane, and thus, the second wiring board 20 may alternatively be a non-flexible wiring board using glass epoxy resin or the like for a substrate.

The chip component 30 is a square according to JIS standard 0603 (EIA standard 0201), and a length L30 between the first end surface 30SA and the second end surface 30SB is 0.6 mm, a width W30 is 0.3 mm, and a thickness t30 is 0.23 mm The chip components 40, 50 are squares according to JIS standard 0402 (EIA standard 01005), and lengths L40, L50 are 0.4 mm, widths W40, W50 are 0 2 mm, and thicknesses t40, t50 are 0.13 mm

The chip component has a dimension which is smaller when the chip component is vertically placed (width W×thickness t) than when the chip component is horizontally placed (length L×width W). That is, the chip components are mounted at a higher density on the three-dimensional wiring board 1 than on a wiring board where the chip components are horizontally placed.

The chip components 30 and the like are chip capacitors, for example; however, if the chip components can be supplied in a state where the chip components are disposed on a carrier tape or the like and can be placed at predetermined positions of the first wiring board 10 by a mounter, the chip components may alternatively be chip resistors or the like. Moreover, the chip component 40 may be a capacitor, and the chip component 50 may be a resistor. Furthermore, three or more kinds of chip components with different sizes may be vertically mounted on the three-dimensional wiring board. Moreover, it is sufficient if at least one chip component is vertically mounted in the recessed portion. Moreover, a chip component may be transversely mounted.

The length L is different between the chip component 30 and the chip components 40, 50. However, the recessed portion H30 where the chip component 30 is vertically placed has a depth D30 according to the length L30 of the chip component 30. Moreover, the recessed portions H40, H50 where the chip components 40, 50 are vertically placed have depths D40, D50 according to the lengths L40, L50 of the chip components 40, 50. Here, a depth D according to the length L of the chip component means that the length L of the chip component and the depth D are substantially the same. Particularly, the depth D of the recessed portion is preferably between 75% and 125% inclusive, or more preferably between 90% and 110% inclusive of the length L of the chip component. Within such a range, the second end electrode of the chip component may be easily solder-joined to the second junction electrode of the second wiring board.

For example, the depth D30 of the recessed portion H30 is preferably between 75% and 125% inclusive of the length L30 (=0.6 mm) of the chip component 30, that is, between 0.45 mm and 0.75 mm inclusive. In the same manner, the depth D40 of the recessed portion H40 is preferably between 75% and 125% inclusive of the length L40 (=0.4 mm) of the chip component 40, that is, between 0.30 mm and 0.5 mm inclusive.

Note that because solder 38, 24 has a thickness, if the depth D of the recessed portion is 95% of the length L of the chip component, the first main surface 10SA of the first wiring board 10 and the first main surface 20SA of the second wiring board 20 are likely to come into surface contact, for example To inject the sealing resin 29 between the first main surface 10SA and the first main surface 20SA, a gap of at least 0.02 mm is preferably present between the two.

The second end surfaces 30SB, 40SB, 50SB of the chip components 30, 40, 50 which are vertically housed in the recessed portions, where the lengths L and the depths D are substantially the same, are positioned on the same plane. Accordingly, when the first main surface 20SA of the second wiring board 20 is placed on the first main surface 10SA of the first wiring board 10, the second junction electrodes 21, 22, 23 and the second end electrodes 32, 42, 52 of the chip components 30, 40, 50 may be easily joined.

Note that with the three-dimensional wiring board 1, the length U of the opening of the recessed portion of the first wiring board 10 is between 0.55 times and 0.9 times inclusive, such as 0.65 times, the length L of the chip component. In the case where the chip component can be perpendicularly inserted into the recessed portion, the length L of the opening may be about the size of the thickness t of the chip component. To efficiently manufacture the three-dimensional wiring board 1, a mounter has to be used. However, a mounter can only transversely place a chip component. Thus, a chip component is not easily vertically housed in a hole of a wiring board. Moreover, a complex step is necessary to connect an upper end electrode of a vertically placed chip component with a wire.

On the other hand, with the three-dimensional wiring board 1, the chip component is transversely placed by a mounter, and is then vertically housed in the recessed portion by gravity.

To vertically house the chip component by gravity, the chip component has to be placed such that a center of gravity G (see FIG. 4) is above the opening. The center of gravity of the chip component in a horizontal direction is at a midpoint of the first end surface and the second end surface, that is, at a position of 0.5 times the length of the chip component from the first end surface. Moreover, the chip component is made vertical from a horizontal state shifting via an inclined state.

Accordingly, the length U of the opening of the recessed portion has to be at least 0.55 times the length L of the chip component, and is more preferably, 0.6 times or more. In other words, in the case where the length U of the opening of the recessed portion is less than 0.55 times the length L of the chip component, the chip component is possibly stopped at an angle inside the recessed portion and is not vertically placed.

Furthermore, if the length U of the opening of the recessed portion is 0.9 times or less the length L of the chip component, chip components may be mounted at a higher density than when the chip components are horizontally placed on the wiring board 10.

Note that to place the chip component at a predetermined position in an in-plane direction (XY direction), the length B of the bottom surface is preferably slightly greater than the thickness t of the chip component.

The length U of the opening and the length B of the bottom surface are different for the recessed portion H30, H40 with a chamfered wall surface. Accordingly, the length B of the bottom surface is made slightly greater than the thickness t of the chip component, such as 1.1t, regardless of the length U of the opening.

On the other hand, the length B of the bottom surface of the recessed portion H50 with no chamfered wall surface is the same as the length U of the opening. As described above, the length U of the opening is at least 0.55 times the length L of the chip component, and is much greater than the thickness t of the chip component. For example, with the chip component 50 according to the JIS standard 0402, 0.55 times the length L50 is 0.22 mm (0.4×0.55), and 1.1 times the thickness t50 is 0.14 mm (0.13 mm×1.1). That is, the length B50 (0.22 mm) of the bottom surface is much greater than the thickness t50 (0.13 mm), and thus, when the chip component 50 is vertically housed, the first end electrode 51 of the chip component 50 and the first junction electrode 59 on the bottom surface 59SA of the recessed portion H50 are possibly shifted in the Y direction.

On the other hand, with the recessed portions H30, H40 with a chamfered wall surface, the position of the first end electrode 31, 41 of the vertically housed chip component 30, 40 approximately coincides with the position of the first junction electrode 39, 49 on the bottom surfaces 39SA, 49SA of the recessed portions H30, H40. Accordingly, with the recessed portions H30, H40 with a chamfered wall surface, joining may be achieved easily and reliably.

Note that with the recessed portion H50 with no chamfered wall surface, even if the position of the first end electrode 51 of the chip component 50 is greatly shifted from the position of the first junction electrode 59 on the bottom surface 59SA of the recessed portion H50, a self-alignment effect by surface tension of solder works at the time of solder-joining, and thus, the chip component 50 may be joined on the first junction electrode 59 in an upright manner.

As described above, the three-dimensional wiring board 1 on which chip components are mounted at a high density may be easily manufactured using a mounter capable of only transversely placing chip components.

### <Manufacturing Method>

Next, a method for manufacturing the three-dimensional wiring board 1 will be described.

As shown in FIGS. 3 and 4, the chip components 30, 40, 50 are horizontally placed on the first main surface 10SA of the first wiring board 10 by an automatic mounting machine. For example, the chip components 30, 40, 50 are each disposed on a carrier tape or the like and set to the automatic mounting machine in a reel state, and are horizontally placed at predetermined positions of the first wiring board 10 based on a program.

Here, for example, the chip component 30 is placed with the center of gravity G above the opening of the recessed portion H30. That is, the chip component 30 is placed with more than half of the length L30 positioned above the opening of the recessed portion H30.

Note that in FIG. 4, for the sake of description, the chip components 30, 40, 50 are shown to be horizontally placed at the same time. However, as described later, a chip component which is horizontally placed on the first wiring board 10 is caused to fall into a recessed portion before a next chip component is placed.

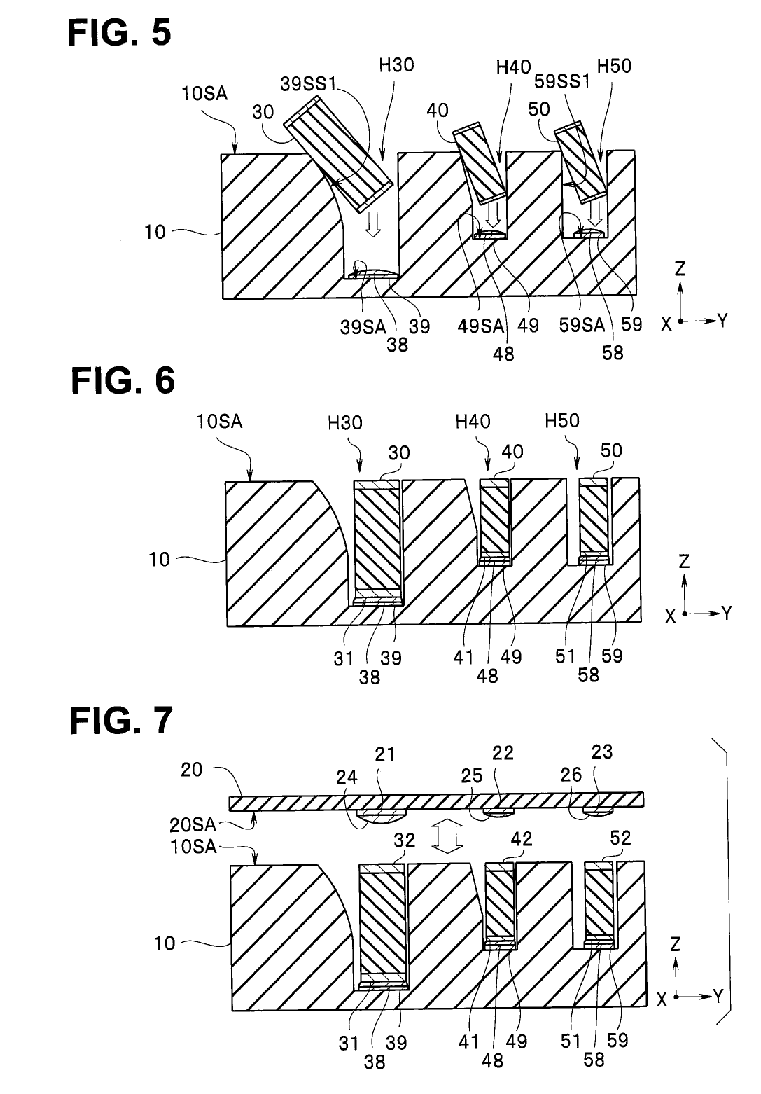

That is, as shown in FIGS. 5 and 6, the chip component 30 which is horizontally placed is automatically vertically housed into the recessed portion H30 while contacting the chamfered surface 39SS1 of the recessed portion H30 due to gravity g. The chip component 50 is automatically vertically housed into the recessed portion H50 while contacting an edge between the wall surface 59SS1 and the first main surface 10SA. The first end electrodes 31, 41, 51 of the chip components 30, 40, 50 are thus placed on the first junction electrodes 39, 49, 59.

Solder pastes 38, 48, 58 for joining are applied on the first junction electrodes 39, 49, 59 by a dispenser having a narrow nozzle before the chip components 30, 40, 50 are disposed.

Note that vibration may be applied as appropriate to house the chip components 30 and the like in the recessed portions H30 and the like.

Next, as shown in FIG. 7, the second wiring board 20 is disposed on the main surface 10SA of the first wiring board 10. The second junction electrodes 21, 22, 23 of the second wiring board 20 are placed on the second end electrodes 32, 42, 52 of the chip components 30, 40, 50. Solder pastes 24, 25, 26 are applied on the second junction electrodes 21, 22, 23 by a dispensing method or a screen printing method.

Note that at least one of the first end electrode, the second end electrode, the first junction electrode, and the second junction electrode may be an electrode including a solder layer formed from an Sn-electroplating film or the like. In such a case, application of a solder paste may be unnecessary.

When reflow processing is performed, the first end electrodes 31, 41, 51 are solder-joined to the first junction electrodes 39, 49, 59, and the second end electrodes 32, 42, 52 are solder-joined to the second junction electrodes 21, 22, 23.

Then, the sealing resin 29 is injected between the first wiring board 10 and the second wiring board 20. Note that the reflow processing may be performed after the first wiring board 10 and the second wiring board 20 are bonded with the sealing resin 29. Furthermore, the reflow processing may be performed for the first wiring board 10 on which the chip components are mounted before the second wiring board 20 is disposed, and the reflow processing may be performed again after the second wiring board 20 is disposed.

As described above, according to the method for manufacturing the three-dimensional wiring board 1, the three-dimensional wiring board 1 on which chip components are mounted at a high density may be easily manufactured by a mounter which can only transversely place chip components.

### Modification of First Embodiment

With the three-dimensional wiring board 1 of the first embodiment, the chip component is horizontally placed with the center of gravity positioned at the opening of the recessed portion, and is vertically housed into the recessed portion by gravity. Accordingly, the length U of the opening of the recessed portion has to be at least 0.55 times the length L of the chip component.

On the other hand, in the case of vertically solder-joining the chip component on the first main surface of the second wiring board and then joining the second wiring board, the length U of the opening of the recessed portion may be less than 0.55 times the length L as long as the length U is greater than the thickness t of the chip component.

For example, by performing the reflow processing after horizontally placing the chip component with the second end surface positioned at a position of a junction electrode, having a solder, of the second wiring board, the chip component may be joined in an upright manner to the first main surface of the second wiring board. Such joining may be realized by a “chip standing phenomenon”, which is a so-called “Manhattan phenomenon” or “tombstone phenomenon”, caused by surface tension of molten solder. That is, the “Manhattan phenomenon”, which was considered to be a problem at the time of surface mounting of a chip component, is actively used.

The three-dimensional wiring board 1 of the modification is a three-dimensional wiring board including a chip electronic component including a first end electrode on a first end surface and a second end electrode on a second end surface opposite the first end surface, and a first wiring board with a recessed portion including a first junction electrode on a bottom surface, where the three-dimensional wiring board further includes a second wiring board, disposed on the first wiring board, including a second junction electrode, the chip electronic component is vertically housed in the recessed portion, the first end electrode is joined to the first junction electrode, and the second end electrode is joined to the second junction electrode.

### Second Embodiment

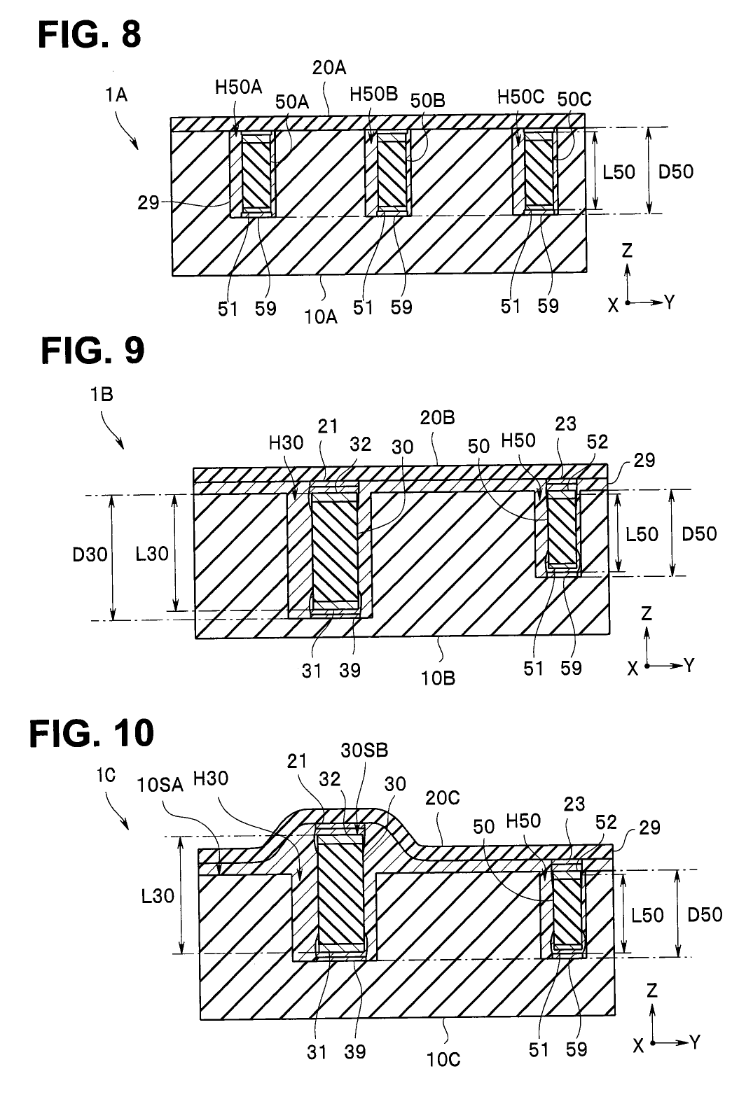

FIG. 8 shows a three-dimensional wiring board 1A according to a second embodiment. The three-dimensional wiring board 1A is similar to the three-dimensional wiring board 1, and the same components are denoted by the same reference signs and description of the components is omitted.

Unlike the three-dimensional wiring board 1, three chip components 50A, 50B, 50C of the three-dimensional wiring board 1A have the same size (length L50). Three recessed portions H50A, H50B, H50C of a first wiring board 10A have the same depth D50, and wall surfaces of the recessed portions are not chamfered.

That is, the three-dimensional wiring board 1A includes the chip electronic components 50A, 50B, 50C, the first wiring board 10A, and a second wiring board 20A, where the chip electronic components 50A, 50B, 50C are vertically housed in the recessed portions H50A, H50B, H50C of the first wiring board 10A, first end electrodes of the chip electronic components 50A, 50B, 50C are joined to first junction electrodes of the first wiring board 10A, and second end electrodes of the chip electronic components 50A, 50B, 50C are joined to second junction electrodes of the first wiring board 10A.

As in the case of the three-dimensional wiring board 1, a method for manufacturing the three-dimensional wiring board 1A includes horizontally placing the chip electronic components 50A, 50B, 50C on the first wiring board 10A with centers of gravity positioned at openings of the recessed portions H50A, H50B, H50C, and causing the chip electronic components 50A, 50B, 50C to be vertically housed in the recessed portions H50A, H50B, H50C by gravity.

Accordingly, the three-dimensional wiring board 1A and the method for manufacturing the three-dimensional wiring board 1A achieve the effects of the three-dimensional wiring board 1 and the method for manufacturing the three-dimensional wiring board 1.

### Third Embodiment

FIG. 9 shows a three-dimensional wiring board 1B according to a third embodiment. The three-dimensional wiring board 1B is similar to the three-dimensional wiring board 1, and the same components are denoted by the same reference signs and description of the components is omitted.

The three-dimensional wiring board 1B includes the chip component 30 according to the JIS standard 0603, and the chip component 50 according to the JIS standard 0402. The recessed portions H30, H50 of a first wiring board 10B have the depths D30, D50 according to the lengths L30, L50 of the chip components 30, 50, and wall surfaces of the recessed portions are not chamfered.

As in the case of the three-dimensional wiring board 1, a method for manufacturing the three-dimensional wiring board 1B includes horizontally placing the chip electronic components 30, 50 on the first wiring board 10B with centers of gravity positioned at openings of the recessed portions H30, H50, and causing the chip electronic components 30, 50 to be vertically housed in the recessed portions H30, H50 by gravity.

Accordingly, the three-dimensional wiring board 1B and the method for manufacturing the three-dimensional wiring board 1B achieve the effects of the three-dimensional wiring board 1 and the method for manufacturing the three-dimensional wiring board 1.

### Fourth Embodiment

FIG. 10 shows a three-dimensional wiring board 1C according to a fourth embodiment. The three-dimensional wiring board 1C is similar to the three-dimensional wiring board 1, and the same components are denoted by the same reference signs and description of the components is omitted.

The three-dimensional wiring board 1C includes the chip component 30 according to the JIS standard 0603, and the chip component 50 according to the JIS standard 0402. The recessed portions H30, H50 of a first wiring board 10C both have the depth D50 according to the length L50 of the chip component 50. Accordingly, the second end surface 30SB of the chip component 30 having the length L30 and vertically housed in the recessed portion H30 protrudes from the first main surface 10SA of the first wiring board 10C.

However, for example, the three-dimensional wiring board 1C uses polyimide for a substrate, has a thickness of 25 μm, and has flexibility, and thus, the first end electrodes 31, 51 are joined to the first junction electrodes 39, 59, and the second end electrodes 32, 52 are joined to the second junction electrodes 21, 23.

Note that the depths of the recessed portions of the three-dimensional wiring board 1C are D50 according to the length L50 of the smallest chip component 50 among a plurality of types of chip components, but the depths may be according to an average length of the plurality of types of chip components as long as the lengths are equal to or greater than the length L50 of the smallest chip component 50.

As in the case of the three-dimensional wiring board 1, a method for manufacturing the three-dimensional wiring board 1C includes horizontally placing the chip electronic components 30, 50 on the first wiring board 10C with centers of gravity positioned at openings of the recessed portions H30, H50, causing the chip electronic components 30, 50 to be vertically housed in the recessed portions H30, H50 by gravity, and placing a flexible second wiring board 20C including the second junction electrodes 21, 22 on an upper surface (first main surface 10SA) of the first wiring board 10C.

Accordingly, the three-dimensional wiring board 1C and the method for manufacturing the three-dimensional wiring board 1C achieve the effects of the three-dimensional wiring board 1 and the method for manufacturing the three-dimensional wiring board 1. Furthermore, because the depths of the recessed portions H30, H50 are the same, the first wiring board 10C can be easily manufactured.

### Fifth Embodiment

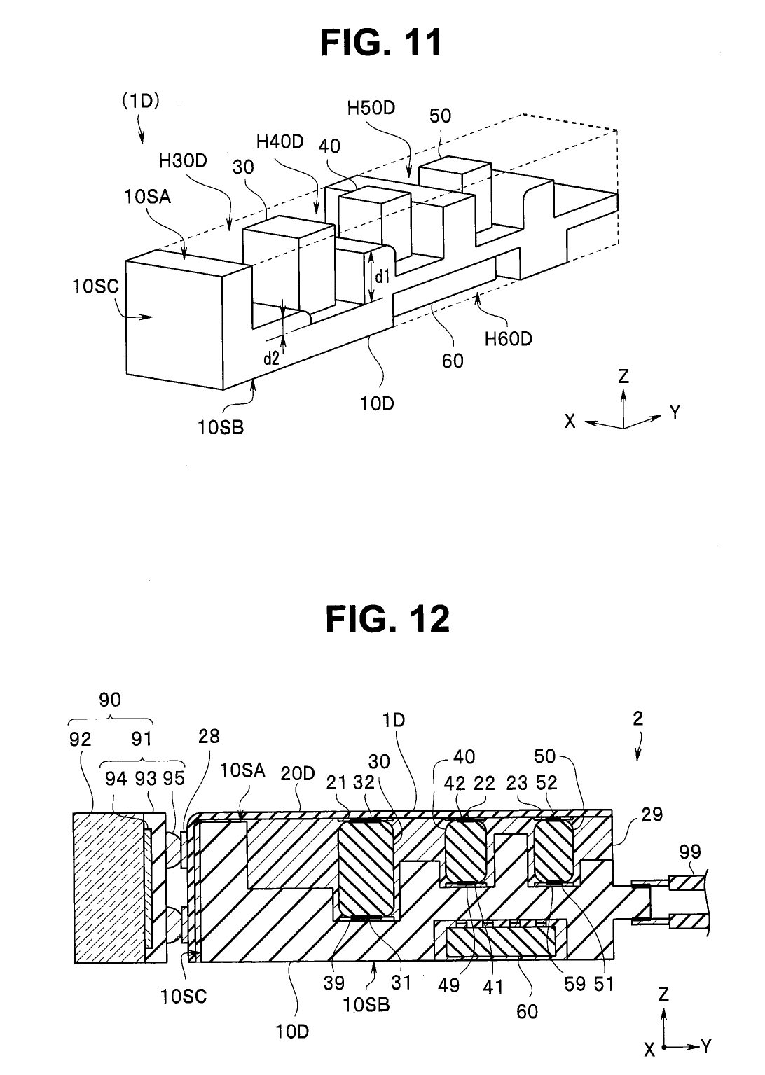

FIGS. 11 and 12 show a three-dimensional wiring board 1D according to a fifth embodiment. The three-dimensional wiring board 1D is similar to the three-dimensional wiring board 1 and achieves the same effect as the three-dimensional wiring board 1, and the same components are denoted by the same reference signs and description of the components is omitted.

Note that FIG. 11 is a perspective view of a first wiring board 10D before a second wiring board 20D is disposed on which the chip components 30, 40, 50 are placed. Furthermore, FIG. 12 is a cross-sectional view of an image pickup apparatus 2 including the three-dimensional wiring board 1D.

As shown in FIG. 11, recessed portions H30D, H40D, H50D, which are opened in directions of two facing wall surfaces, that is, grooves, are formed in the first main surface 10SA of the first wiring board 10D of the three-dimensional wiring board 1D. A solder paste (not shown) can be applied to the recessed portions H30D and the like, which are grooves, from an opening on a side surface. Accordingly, a solder paste can be easily applied to the recessed portion H30D compared with the recessed portions H30 and the like, which are holes.

Note that if a groove is opened at at least one wall surface, the same effect as the recessed portions H30D and the like, which are opened in the directions of two facing wall surfaces, can be achieved.

Furthermore, heights of wall surfaces of the recessed portion (groove) H30D, H40D, H50D are different. For example, with respect to the recessed portion H30D, a height of a chamfered wall surface is d2, and a height of a facing wall surface is d1, and thus, d1>d2 is true.

For example, the chip component 30 is caused to fall into the recessed portion H30D from a part of the opening where the height of the wall surface is low, and is held by the wall surface with a high height. Accordingly, the chip component 30 is easily inserted into the recessed portion H30D, and is stably held due to being in contact with a wall surface with a large area.

Furthermore, the first wiring board 10D also includes a groove H60D on a second main surface 10SB. An electronic component such as a surface mounting IC 60 is mounted inside the groove H60D.

The image pickup apparatus 2 shown in FIG. 12 includes an image pickup unit 90, the three-dimensional wiring board 1D, and a cable 99.

The image pickup unit 90 is formed of an image pickup device chip 91 having a cover glass 92 disposed on a light receiving surface. The image pickup device chip 91 is formed of a semiconductor substrate 93 having a CMOS light receiving portion 94 formed on the light receiving surface and a bump 95 disposed on a rear surface.

The second wiring board 20D is a flexible wiring board, a distal end portion of which is bent at 90 degrees and is fixed to a distal end surface 10SC of the first wiring board 10D. A junction electrode 28 at the distal end portion of the second wiring board 20D is joined to the image pickup device chip 91. The cable 99 is joined to a rear end portion of the first wiring board 10D.

Because the image pickup apparatus 2 includes the three-dimensional wiring board 1D on which chip components are mounted at a high density, the image pickup apparatus 2 is narrow, short and small.

The present invention is not limited to the embodiments, modifications, and the like described above, and various changes, alterations, combinations and the like may be made within the scope of the present invention.

What is claimed is:

1. A three-dimensional wiring board comprising:
a chip electronic component including a first end electrode on a first end surface and a second end electrode on a second end surface opposite the first end surface; and
a first wiring board with a recessed portion including a first junction electrode on a bottom surface, wherein
the three-dimensional wiring board further includes a second wiring board, disposed on the first wiring board, including a second junction electrode, and
the chip electronic component is vertically housed in the recessed portion, the first end electrode is joined to the first junction electrode, the second end electrode is joined to the second junction electrode, and one wall surface of the recessed portion is chamfered.

2. The three-dimensional wiring board according to claim 1, wherein a length of an opening of the recessed portion of the first wiring board is between 0.55 times and 0.9 times inclusive a length of the chip electronic component.

3. The three-dimensional wiring board according to claim 1, comprising a plurality of electronic components, where a length between the first end surface and the second end surface is different for the plurality of electronic components, wherein
the plurality of electronic components are housed in recessed portions of depths according to respective lengths.

4. The three-dimensional wiring board according to claim 3, wherein the depths of the recessed portions are between 75% and 125% inclusive of the lengths of the corresponding electronic components housed in the recessed portions.

5. The three-dimensional wiring board according to claim 1, wherein heights of facing wall surfaces of the recessed portion are different.

6. The three-dimensional wiring board according to claim 1, wherein the recessed portion is a groove opened at at least one side surface.

7. A method for manufacturing a three-dimensional wiring board including a chip electronic component including a first end electrode on a first end surface and a second end electrode on a second end surface opposite the first end surface, and a first wiring board with a recessed portion including a first junction electrode on a bottom surface, the method comprising:
horizontally placing the chip electronic component on the first wiring board with a center of gravity of the chip electronic component positioned at an opening of the recessed portion;
causing the chip electronic component to be vertically housed in the recessed portion by gravity;
placing a second wiring board including a second junction electrode on an upper surface of the first wiring board; and
solder-joining, by reflow processing, the first end electrode and the first junction electrode, and the second end electrode and the second junction electrode.

8. The method for manufacturing a three-dimensional wiring board according to claim 7, wherein placing the chip electronic component on the first wiring board is performed by an automatic mounting machine.
